(19) United States
(12) Patent Application Publication
(10) Pub. No.: US 2011/0061923 A1
(43) Pub. Date: Mar. 17, 2011

(54) DOUBLE-SIDED PRESSURE-SENSITIVE ADHESIVE TAPE AND WIRING CIRCUIT BOARD

(75) Inventors: Takahiro Nonaka, Osaka (JP); Noritsugu Daigaku, Osaka (JP); Masahiro Ooura, Osaka (JP)

(73) Assignee: NITTO DENKO CORPORATION, Ibaraki-shi (JP)

(21) Appl. No.: 12/736,803

(22) PCT Filed: Apr. 24, 2009
(86) PCT No.: PCT/JP2009/001880

§ 371 Date: Nov. 10, 2010

(30) Foreign Application Priority Data
May 13, 2008 (JP) 2008-126127

(51) Int. Cl. H05K 1/02; B32B 7/12

(52) U.S. Cl. 174/268; 428/336

(57) ABSTRACT

A double-sided pressure-sensitive adhesive tape includes a nonwoven fabric substrate and pressure-sensitive adhesive layers present on both sides of the substrate, in which the nonwoven fabric substrate contains at least Manila hemp, has a thickness of 18 μm or less, and has a tensile strength in a machine direction of 4 N/15 mm or more. The double-sided pressure-sensitive adhesive tape is thin and is effective for the reduction in size and thickness of products to be fixed through the tape. The tape has a high strength in the machine direction and does not break during production and processing processes. In addition, the tape has a nonwoven fabric substrate and thereby excels also in punching quality. The tape is therefore particularly useful as a double-sided pressure-sensitive adhesive tape for fixing a wiring circuit board.

### TECHNICAL FIELD

The present invention relates to a double-sided pressure-sensitive adhesive tape. More specifically, it relates to a double-sided pressure-sensitive adhesive tape adopted to a wiring circuit board and to a wiring circuit board using the double-sided pressure-sensitive adhesive tape.

### BACKGROUND ART

In electronic instruments, wiring circuit boards are used, of which flexible printed circuit boards (hereinafter also referred to as “FPC(s)”) have been widely used. Usually, wiring circuit boards such as FPCs are used in a state of being bonded to a reinforcing plate (such as aluminum plate, stainless steel plate or polyimide plate) and the bonding is performed using a double-sided pressure-sensitive adhesive tape or sheet (double-sided pressure-sensitive adhesive tape or sheet for wiring circuit boards) (hereinafter such a double-sided pressure-sensitive adhesive tape or sheet is generically referred to as a “double-sided pressure-sensitive adhesive tape”). As such double-sided pressure-sensitive adhesive tape, a double-sided pressure-sensitive adhesive tape formed by adhesive layers alone (the so-called “substrate-less double-sided pressure-sensitive adhesive tape”) has been widely used in view of having a smaller total thickness (see Patent Literature 1). However, since the substrate-less double-sided pressure-sensitive adhesive tape has no substrate, it shows disadvantages in workability such that it is not suitable for fine punching or blanking process or the pressure-sensitive adhesive layer protrudes out during punching (blanking).

Independently, some double-sided pressure-sensitive adhesive tapes are known as double-sided pressure-sensitive adhesive tapes having improved workability. These are double-sided pressure-sensitive adhesive tapes each including a core material formed from a nonwoven fabric, and pressure-sensitive adhesive layers present on both sides of the core material (see Patent Literatures 2 and 3). Even these substrate-supported double-sided pressure-sensitive adhesive tapes, however, show insufficient strengths to cause problems such as tape breakage during production processes when the nonwoven fabric substrate is designed to have a small thickness.

### Citation List

### Patent Literature

PTL 1: Japanese Unexamined Patent Application Publication (JP-A) No. 2001-40301

PTL 2: Japanese Unexamined Patent Application Publication (JP-A) No. 2006-302941

PTL 3: Japanese Unexamined Patent Application Publication (JP-A) No. 2007-302868

### SUMMARY OF INVENTION

### Technical Problem

Accordingly, an object of the present invention is to provide a double-sided pressure-sensitive adhesive tape which is thin, but is highly strong and shows satisfactory productivity and workability. Another object of the present invention is to provide a wiring circuit board using the double-sided pressure-sensitive adhesive tape.

### Solution to Problem

After intensive investigations to achieve the objects, the present inventors have found that, by using a nonwoven fabric substrate containing at least Manila hemp and having a tensile strength in a machine direction of 4 N/15 mm or more as a substrate of a double-sided pressure-sensitive adhesive tape, the resulting double-sided pressure-sensitive adhesive tape is thin, but is highly strong and shows satisfactory productivity and workability. The present invention has been made based on these findings.

Specifically, the present invention provides, in an embodiment, a double-sided pressure-sensitive adhesive tape which includes a nonwoven fabric substrate; and a pair of pressure-sensitive adhesive layers present on both sides of the substrate, in which the nonwoven fabric substrate contains at least Manila hemp, has a thickness of 18 μm or less and has a tensile strength in a machine direction of 4 N/15 mm or more.

In the double-sided pressure-sensitive adhesive tape, the pressure-sensitive adhesive layer may be formed from a pressure-sensitive adhesive composition containing an acrylic polymer as a principal component and further containing a tackifier resin having phenolic hydroxyl groups.

The double-sided pressure-sensitive adhesive tape may be adopted to a wiring circuit board.

In another embodiment, the present invention provides a wiring circuit board which includes an electrically insulating layer; and an electrically conducting layer present on or above the electrically insulating layer so as to form a predetermined circuit pattern, in which the wiring circuit board further includes the double-sided pressure-sensitive adhesive tape affixed to a back side of the wiring circuit board.

### ADVANTAGEOUS EFFECTS OF INVENTION

The double-sided pressure-sensitive adhesive tape according to the present invention is thin and is effective for the reduction in size and thickness of products using the tape for fixing. The double-sided pressure-sensitive adhesive tape has a high strength in the machine direction and is thereby resistant to breakage during production and processing processes. In addition, the double-sided pressure-sensitive adhesive tape has a nonwoven fabric substrate and thereby excels also in punching quality (punching workability).

### DESCRIPTION OF EMBODIMENTS

A double-sided pressure-sensitive adhesive tape according to an embodiment of the present invention includes a nonwoven fabric substrate; and a pair of pressure-sensitive adhesive layers present on or above both sides of the nonwoven fabric substrate. As used herein the term “double-sided pressure-sensitive adhesive tape” means and includes one in the form of a tape and one in the form of a sheet. Specifically, this term generically refers to and includes both a double-sided pressure-sensitive adhesive tape and a double-sided pressure-sensitive adhesive sheet.

[Nonwoven Fabric Substrate]

A nonwoven fabric constituting the nonwoven fabric substrate used in the double-sided pressure-sensitive adhesive tape according to the present invention includes at least Manila hemp (Manila hemp fibers). The presence of the Manila hemp helps the nonwoven fabric substrate to have improved thermal stability and to be resistant to heat-induced deterioration in strength. The nonwoven fabric substrate has a content of Manila hemp of preferably 50 percent by weight or more (50 to 100 percent by weight) and more preferably 70 percent by weight or more, based on the total weight of fibers constituting the nonwoven fabric substrate. The nonwoven fabric substrate, if having a content of Manila hemp of less than 50 percent by weight, may show insufficient thermal stability and/or may have an insufficient tensile strength.

Though not limited, examples of fibers, other than Manila hemp, for constituting the nonwoven fabric include pulp; and chemical fibers such as rayon, acetate fibers, polyester fibers, poly(vinyl alcohol) fibers, polyamide fibers, and polyolefin fibers. Among them, preferred from the viewpoint of tensile strength are nonwoven fabrics containing Manila hemp alone; and nonwoven fabrics containing a mixture of Manila hemp and pulp (wood pulp). Of such mixed nonwoven fabrics, a nonwoven fabric typically containing 80 percent by weight of Manila hemp and 20 percent by weight of pulp is more preferred.

The nonwoven fabric substrate may be impregnated with a resin (binder) so as to bond nonwoven fabric fibers with each other and to improve the strength. Examples of the binder include thermoplastic resins such as viscose, carboxymethylcellulose, poly(vinyl alcohol)s and polyacrylamides.

The way to form the nonwoven fabric substrate can be any paper making process not limited and can be a known or customary wet paper making process. Likewise, a paper machine usable herein is not limited, and examples thereof include paper machines such as a cylinder paper machine, a tanmo paper machine, a wire paper machine (Fourdrinier paper machine), and an inclined tanmo paper machine. Among them, a cylinder paper machine is preferred for providing a nonwoven fabric substrate having a high tensile strength.

The nonwoven fabric substrate has a basis weight (grammage) of preferably 4 to 8 g/m² and more preferably 5 to 7 g/m². The nonwoven fabric, if having a basis weight of less than 4 g/m², may have an insufficient tensile strength and may often cause tape breakage. In contrast, the nonwoven fabric, if having a basis weight of more than 8 g/m², may cause difficulties in the production of a thin double-sided pressure-sensitive adhesive tape.

The nonwoven fabric substrate has a tensile strength in a machine direction (MD) of 4 N/15 mm or more (e.g., 4 to 10 N/15 mm) and preferably 4 to 7 N/15 mm. The nonwoven fabric substrate, if having a tensile strength in MD of less than 4 N/15 mm, may often cause or suffer rupture of the double-sided pressure-sensitive adhesive tape or of the nonwoven fabric substrate itself (the double-sided pressure-sensitive adhesive tape may be liable to break), due to tension in the machine direction applied during production processes, processing processes and affixation of the double-sided pressure-sensitive adhesive tape. The term “machine direction (MD)” refers to a direction of a production line of the nonwoven fabric and is generally a longitudinal direction (lengthwise direction) of the double-sided pressure-sensitive adhesive tape. The “tensile strength” refers to a “tensile strength” in units of “N/15 mm” as determined by a tensile test according to the method described in Japanese Industrial Standards (JIS) P 8113.

Though not critical, the nonwoven fabric substrate has a tensile strength in a width direction (transverse direction (TD)) of preferably 0.2 to 1 N/15 mm. The nonwoven fabric substrate, if having a tensile strength in TD of less than 0.2 N/15 mm, may cause inferior workability. The term “transverse direction (TD)” refers to a direction perpendicular to the machine direction (MD).

The nonwoven fabric substrate has a thickness of 18 μm or less (e.g., 5 to 18 μm), preferably 10 to 18 μm, and more preferably 12 to 18 μm. The nonwoven fabric substrate, if having a thickness of more than 18 μm, causes the double-sided pressure-sensitive adhesive tape to have an excessively large thickness, and the resulting double-sided pressure-sensitive adhesive tape, when used for fixing in a product, does not contribute to a smaller thickness of the product. An example of the product herein is an electronic instrument using an FPC which is fixed to a reinforcing plate through the double-sided pressure-sensitive adhesive tape. In contrast, the nonwoven fabric substrate, if having an excessively small thickness of less than 5 μm, may cause deterioration in punching quality and/or handleability.

[Pressure-Sensitive Adhesive Layers]

The pressure-sensitive adhesive layers in the double-sided pressure-sensitive adhesive tape according to the present invention are each preferably formed from a pressure-sensitive adhesive composition containing an acrylic polymer as a principal component and further containing a tackifier resin having a phenolic hydroxyl group. The acrylic polymer plays a role of developing tackiness as a base polymer for constituting the pressure-sensitive adhesive layers. The pressure-sensitive adhesive composition has a content of the principal component acrylic polymer of preferably 70 percent by weight or more, more preferably 70 to 90 percent by weight and furthermore preferably 75 to 85 percent by weight, based on the total solids content of the composition.

(Acrylic Polymer)

The acrylic polymer is preferably an acrylic polymer formed from one or more alkyl (meth)acrylates as a principal monomer component (monomer main component). The alkyl (meth)acrylates are alkyl esters of (meth)acrylic acids whose alkyl moiety being a linear or branched-chain alkyl group. Examples of the alkyl (meth)acrylates include alkyl (meth)acrylates whose alkyl moiety being a linear or branched-chain alkyl group having 1 to 20 carbon atoms, such as methyl (meth)acrylates, ethyl (meth)acrylates, propyl (meth)acrylates, isopropyl (meth)acrylates, butyl (meth)acrylates, isobutyl (meth)acrylates, s-butyl (meth)acrylates, t-butyl (meth)acrylates, pentyl (meth)acrylates, isopentyl (meth)acrylates, hexyl (meth)acrylates, heptyl (meth)acrylates, octyl (meth)acrylates, 2-ethylhexyl (meth)acrylates, isooctyl (meth)acrylates, nonyl (meth)acrylates, isononyl (meth)acrylates, decyl (meth)acrylates, isodecyl (meth)acrylates, undecyl (meth)acrylates, dodecyl (meth)acrylates, tridecyl (meth)acrylates, tetradecyl (meth)acrylates, pentadecyl (meth)acrylates, hexadecyl (meth)acrylates, heptadecyl (meth)acrylates, octadecyl (meth)acrylates, nonadecyl (meth)acrylates and eicosyl (meth)acrylates. Among them, alkyl (meth)acrylates whose alkyl moiety being a linear or branched-chain alkyl group having 2 to 14 carbon atoms (more preferably 2 to 10 carbon atoms) are preferred.

For exhibiting satisfactory properties such as tackiness, the proportion of the alkyl (meth)acrylates in the composition is preferably 60 percent by weight or more, more preferably 80 percent by weight or more and furthermore preferably 90 percent by weight or more, based on the total amount of monomer components for the preparation of the acrylic polymer. Though not critical in the upper limit, the proportion is preferably 99 percent by weight or less, more preferably 98 percent by weight or less, and furthermore preferably 97 percent by weight or less.

The acrylic polymer may further include (be formed from) one or more copolymerizable monomers such as polar-group-containing monomers and multifunctional monomers. The use of copolymerizable monomers as monomer components allows the pressure-sensitive adhesive (tacky adhesive) to have a higher bond strength to an adherend and/or to have a higher cohesive strength. Each of different copolymerizable monomers can be used alone or in combination.

Examples of the polar-group-containing monomers include carboxyl-containing monomers such as (meth)acrylic acids, itaconic acid, maleic acid, fumaric acid, crotonic acid and isocrotonic acid, and anhydrides of them, such as maleic anhydride; hydroxyl-containing monomers including hydroxyalkyl (meth)acrylates such as hydroxyethyl (meth)acrylates, hydroxypropyl (meth)acrylates and hydroxybutyl (meth)acrylates; amido-containing monomers such as acrylamide, methacrylamide, N,N-dimethyl(meth)acrylamides, N-methylol(meth)acrylamides, N-methoxymethyl(meth)acrylamides, and N-butoxymethyl(meth)acrylamides; amino-containing monomers such as aminoethyl (meth)acrylates, dimethylaminoethyl (meth)acrylates and t-butylaminoethyl(meth)acrylates; glycidyl-containing monomers such as glycidyl (meth)acrylates and methylglycidyl (meth)acrylates; cyano-containing monomers such as acrylonitrile and methacrylonitrile; heterocycle-containing vinyl monomers such as N-vinyl-2-pyrrolidone, (meth)acryloylmorpholines, N-vinylpyridine, N-vinylpiperidone, N-vinylpyrimidine, N-vinylpiperazine, N-vinylpyrrole, N-vinylimidazole and N-vinyloxazole; alkoxyalkyl (meth)acrylate monomers such as methoxyethyl (meth)acrylates and ethoxyethyl (meth)acrylates; sulfo-containing monomers such as sodium vinylsulfonate; phosphate-containing monomers such as 2-hydroxyethyl acryloyl phosphate; imido-containing monomers such as cyclohexylmaleimide and isopropylmaleimide; and isocyanato-containing monomers such as 2-methacryloyloxyethyl isocyanate. Of polar-group-containing monomers, carboxyl-containing monomers, such as acrylic acid, and anhydrides of them are preferred, of which acrylic acid is especially preferred.

The proportion of the polar-group-containing monomers is preferably 30 percent by weight or less (e.g., 1 to 30 percent by weight) and more preferably 3 to 20 percent by weight, based on the total amount of monomer components for the formation of the acrylic polymer. In this connection, the proportion of the carboxyl-containing monomers and anhydrides of them (especially of acrylic acid) preferably falls within the above-specified range. Polar-group-containing monomers, if used in an amount of more than 30 percent by weight, may cause the acrylic pressure-sensitive adhesive to have an excessively high cohesive strength and may thereby cause the pressure-sensitive adhesive layers to show an insufficient tackiness. Polar-group-containing monomers, if used in an excessively small amount (e.g., less than 1 percent by weight based on the total amount of monomer components for the formation of the acrylic polymer) may cause the acrylic pressure-sensitive adhesive to have an insufficient cohesive strength to fail to provide a high shear force.

Examples of the multifunctional monomers include hexanediol di(meth)acrylates, butanediol di(meth)acrylates, (poly)ethylene glycol di(meth)acrylates, (poly)propylene glycol di(meth)acrylates, neopentyl glycol di(meth)acrylates, pentaerythritol di(meth)acrylates, pentaerythritol tri(meth)acrylates, dipentaerythritol hexa(meth)acrylates, trimethylolpropane tri(meth)acrylates, tetramethylolmethane tri(meth)acrylates, allyl (meth)acrylates, vinyl (meth)acrylates, divinylbenzene, epoxy acrylates, polyester acrylate, and urethane acrylates.

The proportion of multifunctional monomers is 2 percent by weight or less (e.g., 0.01 to 2 percent by weight) and preferably 0.02 to 1 percent by weight, based on the total amount of monomer components for the formation of the acrylic polymer. Multifunctional monomers, if used in an amount of more than 2 percent by weight based on the total amount of monomer components for the formation of the acrylic polymer, may typically cause the pressure-sensitive adhesive to have an excessively high cohesive strength and to have an insufficient tackiness. Multifunctional monomers, if used in an excessively small amount (e.g., less than 0.01 percent by weight based on the total amount of monomer components for the formation of the acrylic polymer), may typically cause the pressure-sensitive adhesive to have an insufficient cohesive strength.

Exemplary other copolymerizable monomers than the polar-group-containing monomers and multifunctional monomers include (meth)acrylates having an alicyclic hydrocarbon group, such as cyclopentyl (meth)acrylates, cyclohexyl (meth)acrylates and isobornyl (meth)acrylates; aryl (meth)acrylates such as phenyl (meth)acrylates; vinyl esters such as vinyl acetate and vinyl propionate; aromatic vinyl compounds such as styrene and vinyltoluenes; olefins or dienes such as ethylene, butadiene, isoprene and isobutylene; vinyl ethers such as vinyl alkyl ethers; and vinyl chloride.

The acrylic polymer can be prepared according to a known or customary polymerization process. Exemplary polymerization processes of the acrylic polymer include solution polymerization, emulsion polymerization, bulk polymerization, and polymerization through the application of an ultraviolet ray. The polymerization of the acrylic polymer can be performed while using suitable components (e.g., polymerization initiators, chain-transfer agents, emulsifiers and solvents) chosen from among known or customary ones according to the type of the polymerization process.

The acrylic polymer has a weight-average molecular weight of typically preferably 70×10⁴ to 200×10⁴, more preferably 80×10⁴ to 170×10⁴, and furthermore preferably 90×10⁴ to 140×10⁴. The acrylic polymer, if having a weight-average molecular weight of less than 70×10⁴, may not exhibit satisfactory adhesive (tacky adhesive) properties; and, in contrast, the acrylic polymer, if having a weight-average molecular weight of more than 200×10⁴, may cause problems in coatability of the composition, thus being undesirable. The weight-average molecular weight of the acrylic polymer can be controlled through the types and amounts of polymerization initiators and chain-transfer agents, the temperature and time (duration) of the polymerization, and the concentrations and dropping rates of monomers.

(Phenolic-Hydroxyl-Containing Tackifier Resin)

The pressure-sensitive adhesive composition for forming the pressure-sensitive adhesive layers of the double-sided pressure-sensitive adhesive tape according to the present invention preferably further contains a tackifier resin having one or more phenolic hydroxyl groups (hydroxyl-containing aromatic ring) (hereinafter also referred to as a “phenolic-hydroxyl-containing tackifier resin”). The phenolic-hydroxyl-containing tackifier resin is capable of imparting tackiness to the pressure-sensitive adhesive composition or to the pressure-sensitive adhesive layers to thereby improve the adhesiveness. The phenolic-hydroxyl-containing tackifier resin also plays a role of scavenging free radicals. Specifically, even if the pressure-sensitive adhesive layers (acrylic polymer) suffer from the formation of free-radical components typically through a high-temperature process, the phenolic-hydroxyl-containing tackifier resin can effectively inactivate the free-radical components. This protects the acrylic polymer from deterioration (gelation) even when the double-sided pressure-sensitive adhesive tape is adopted typically to an FPC and is exposed to high-temperature conditions typically in a solder reflow step. In other words, this allows the pressure-sensitive adhesive layers to maintain satisfactory adhesiveness even after being subjected to a high-temperature process. Additionally, the nonwoven fabric substrate is satisfactorily impregnated with such phenolic-hydroxyl-containing tackifier resin, and this reduces the air content in the substrate and thereby prevents poor appearance due to expansion of air during a high-temperature process.

Of such phenolic-hydroxyl-containing tackifier resins, preferred are phenol-modified terpene tackifier resins (terpene-phenolic tackifier resins), phenol-modified rosin tackifier resins (rosin-phenolic tackifier resins) and phenolic tackifier resins. Among them, terpene-phenolic tackifier resins are especially preferred from the viewpoint of repulsion resistance after reflowing.

Exemplary terpene-phenolic tackifier resins include resins obtained by modifying various terpene resins (e.g., α-pinene polymers, β-pinene polymers and dipentene polymers) with phenol.

Exemplary rosin-phenolic tackifier resins include resins (phenol-modified rosins) obtained by adding phenol to various rosins (e.g., unmodified rosins, modified rosins and rosin derivatives) using an acid catalyst and thermally polymerizing the adduct.

Examples of the phenolic tackifier resins include condensates of phenols and formaldehyde, such as alkylphenol resins, phenol formaldehyde resins, and xylene formaldehyde resins. Exemplary phenols herein include phenol; resorcinol; cresols such as m-cresol and p-cresol; xylenols such as 3,5-xylenol; and alkylphenols such as p-isopropylphenol, p-t-butylphenol, p-amylphenol, p-octylphenol, p-nonylphenol and p-dodecylphenol. Of such alkylphenols, p-alkylphenols are preferred. Examples of the phenolic tackifier resins further include resols obtained by subjecting any of the phenols and formaldehyde to an addition reaction by the catalysis of an alkaline catalyst; and novolaks obtained by subjecting any of the phenols and formaldehyde to a condensation reaction by the catalysis of an acid catalyst. Though not critical, the alkyl groups in the alkylphenols can each have carbon atom(s) in a number ranging typically from 1 to 18. Of phenolic tackifier resins, alkylphenol resins and xylene-formaldehyde resins are preferred, of which alkylphenol resins are more preferred.

The phenolic-hydroxyl-containing tackifier resin for use herein is preferably one having a softening point of 80° C. or above and more preferably one having a softening point of 100° C. or above, from the viewpoints typically of thermal stability.

Though not critical, the phenolic-hydroxyl-containing tackifier resin may be used in an amount of preferably 5 to 45 parts by weight, more preferably 10 to 40 parts by weight, and furthermore preferably 20 to 40 parts by weight, per 100 parts by weight of the acrylic polymer in the pressure-sensitive adhesive composition. The phenolic-hydroxyl-containing tackifier resin, if used in an amount of less than 5 parts by weight, may not sufficiently effectively prevent an increased gel fraction (solvent-insoluble content). In contrast, the phenolic-hydroxyl-containing tackifier resin, if used in an amount of more than 45 parts by weight, may cause the pressure-sensitive adhesive composition to show insufficient tack and to have insufficient adhesiveness (tackiness).

(Other Components)

Where necessary, the pressure-sensitive adhesive composition for forming the pressure-sensitive adhesive layers of the double-sided pressure-sensitive adhesive tape according to the present invention may further contain known additives within a range not adversely affecting the advantages of the present invention, in addition to the acrylic polymer and phenolic-hydroxyl-containing tackifier resin. Exemplary additives include age inhibitors, fillers, colorants (e.g., pigments and dyestuffs), ultraviolet absorbers, antioxidants, tackifiers other than phenolic-hydroxyl-containing tackifier resins, chain-transfer agents, plasticizers, softeners, crosslinking agents, surfactants, and antistatic agents.

The crosslinking agents crosslink the polymer in the pressure-sensitive adhesive layers and thereby allow the pressure-sensitive adhesive layers to have a controlled gel fraction (content of solvent-insoluble matter). Exemplary crosslinking agents include isocyanate crosslinking agents, epoxy crosslinking agents, melamine crosslinking agents, peroxide crosslinking agents, urea crosslinking agents, metal alkoxide crosslinking agents, metal chelate crosslinking agents, metal salt crosslinking agents, carbodiimide crosslinking agents, oxazoline crosslinking agents, aziridine crosslinking agents, and amine crosslinking agents. Among them, isocyanate crosslinking agents and epoxy crosslinking agents are advantageously usable. Each of different crosslinking agents can be used alone or in combination.

Examples of the isocyanate crosslinking agents include lower aliphatic polyisocyanates such as 1,2-ethylene diisocyanate, 1,4-butylene diisocyanate and 1,6-hexamethylene diisocyanate; alicyclic polyisocyanates such as cyclopentylene diisocyanate, cyclohexylene diisocyanate, isophorone diisocyanate, hydrogenated tolylene diisocyanate and hydrogenated xylene diisocyanate; and aromatic polyisocyanates such as 2,4-tolylene diisocyanate, 2,6-tolylene diisocyanate, 4,4″-diphenylmethane diisocyanate and xylylene diisocyanate. The examples further include an adduct of trimethylolpropane and tolylene diisocyanate [trade name “CORONATE L” supplied by Nippon Polyurethane Industry Co., Ltd.] and an adduct of trimethylolpropane and hexamethylene diisocyanate [trade name “CORONATE HL” supplied by Nippon Polyurethane Industry Co., Ltd.].

Examples of the epoxy crosslinking agents include N,N,N′,N′-tetraglycidyl-m-xylenediamine, diglycidylaniline, 1,3-bis(N,N-diglycidylaminomethyl)cyclohexane, 1,6-hexanediol diglycidyl ether, neopentyl glycol diglycidyl ether, ethylene glycol diglycidyl ether, propylene glycol diglycidyl ether, polyethylene glycol diglycidyl ethers, polypropylene glycol diglycidyl ethers, sorbitol polyglycidyl ethers, glycerol polyglycidyl ethers, pentaerythritol polyglycidyl ethers, polyglycerol polyglycidyl ethers, sorbitan polyglycidyl ethers, trimethylolpropane polyglycidyl ethers, diglycidyl adipate, o-diglycidyl phthalate, triglycidyl tris(2-hydroxyethyl)isocyanurate, resorcinol diglycidyl ether and bisphenol-S diglycidyl ether; as well as epoxy resins each having two or more epoxy groups per molecule. Exemplary commercially available products usable as the epoxy crosslinking agents include a product supplied by Mitsubishi Gas Chemical Company, Inc. under the trade name “TETRAD C”.

The chain-transfer agents usable herein can be chosen as appropriate from known chain-transfer agents, including hydroxyl-containing chain-transfer agents such as benzyl alcohol, α-methylbenzyl alcohol and hydroquinone; thiol-containing chain-transfer agents such as alkyl mercaptans (e.g., octyl mercaptan, lauryl mercaptan and stearyl mercaptan), benzyl mercaptan, glycidyl mercaptan, thioglycolic acid (mercaptoacetic acid), 2-ethylhexyl thioglycolate, octyl thioglycolate, methoxybutyl thioglycolate, 3-mercaptopropionic acid, octyl mercaptopropionate, methoxybutyl mercaptopropionate, 2-mercaptoethanol, 3-mercapto-1,2-propanediol, 2,3-dimethylcapto-1-propanol and thioglycerol; and α-methylstyrene dimer. Each of different chain-transfer agents can be used alone or in combination.

The pressure-sensitive adhesive composition for forming the pressure-sensitive adhesive layers of the double-sided pressure-sensitive adhesive tape according to the present invention can be prepared, for example, by blending components such as the acrylic polymer, the phenolic-hydroxyl-containing tackifier resin, and various additives according to necessity.

The way to form the pressure-sensitive adhesive layers of the double-sided pressure-sensitive adhesive tape according to the present invention is not critical and can be chosen as appropriate from known processes for forming pressure-sensitive adhesive layers. Specifically, the pressure-sensitive adhesive layers can be formed, for example, by a direct application process in which the pressure-sensitive adhesive composition is applied to the surface of a nonwoven fabric substrate so as to have a predetermined dry thickness, and the applied layer is dried or cured according to necessity; or by a transfer process in which the pressure-sensitive adhesive composition is applied to a suitable separator (e.g., release paper) so as to have a predetermined dry thickness and is dried or cured according to necessity to form a pressure-sensitive adhesive layer, and the pressure-sensitive adhesive layer is transferred (moved) to the surface of the nonwoven fabric substrate. For providing pressure-sensitive adhesive layers having smooth surfaces, a transfer/transfer technique is preferred in which both of pressure-sensitive adhesive layers are formed on the both sides of the nonwoven fabric substrate by the transfer process.

The application of the pressure-sensitive adhesive composition can be performed by using a customary coater or, applicator such as gravure roll coater, reverse roll coater, kiss roll coater, dip roll coater, bar coater; knife coater, or spray coater.

Though not critical, each of the pressure-sensitive adhesive layers has a thickness (as one layer) of typically preferably 5 to 60 μm, more preferably 10 to 50 μm, and furthermore preferably 15 to 25 μm. The pressure-sensitive adhesive layers, if each having a thickness of less than 5 μm, may not provide satisfactory adhesiveness. In contrast, the pressure-sensitive adhesive layers, if each having a thickness of more than 60 μm, can show inferior workability. Each of the pressure-sensitive adhesive layers can have a single-layer structure or multilayer structure. When a pressure-sensitive adhesive layer is formed by the transfer process, the term “thickness of the pressure-sensitive adhesive layer” refers typically to the thickness of the pressure-sensitive adhesive layer which has been formed on the separator but is before being transferred to the nonwoven fabric substrate.

[Double-Sided Pressure-Sensitive Adhesive Tape]

The double-sided pressure-sensitive adhesive tape according to the present invention is, as is described above, a substrate-supported double-sided pressure-sensitive adhesive tape including a nonwoven fabric substrate and a pair of pressure-sensitive adhesive layers present on both sides of the substrate. The double-sided pressure-sensitive adhesive tape according to the present invention is of a substrate-supported type, thereby shows satisfactory workability in fine punching process and does not suffer problems such as squeezing or protruding out of the pressure-sensitive adhesive layers during processing. The double-sided pressure-sensitive adhesive tape employs a thin nonwoven fabric substrate and is thereby suitable for the reduction in size and thickness of products which are produced through fixing by using the double-sided pressure-sensitive adhesive tape. In addition, the double-sided pressure-sensitive adhesive tape is highly thermally stable, does not break during production and processing processes and excels in productivity and workability, because it employs, as the substrate, a nonwoven fabric including Manila hemp and having high strength in a machine direction.

The double-sided pressure-sensitive adhesive tape according to the present invention has a total thickness (thickness from one adhesive face to the other adhesive face) of 20 to 120 μm, more preferably 30 to 100 μm, and furthermore preferably 30 to 60 μm, for ensuring satisfactory strength and good workability and for allowing the product to be thin.

The surfaces (adhesive faces) of the pressure-sensitive adhesive layers of the double-sided pressure-sensitive adhesive tape according to the present invention are preferably protected by a release liner (separator) or liners before use. The two adhesive faces of the double-sided pressure-sensitive adhesive tape may be protected by two release liners, respectively, or the double-sided pressure-sensitive adhesive tape may be wound as a roll while the two adhesive faces are protected by one release liner having release surfaces on both sides thereof. The release liner or liners are used as protecting materials for the adhesive faces and will be removed upon the affixation of the double-sided pressure-sensitive adhesive tape to an adherend. It is not always necessary to provide a release liner or liners.

The release liner (separator) can be, for example, a customary release paper, and examples thereof include bases having a release coating layer; low-adhesive bases composed of fluorine-containing polymers; and low-adhesive bases composed of nonpolar polymers. Examples of the bases having a release coating layer include plastic films and papers whose surface having been treated with a release coating agent such as a silicone, long-chain alkyl, fluorine-containing, or molybdenum sulfide release coating agent. Examples of the fluorine-containing polymers constituting the fluorine-containing-polymer low-adhesive bases include polytetrafluoroethylenes, polychlorotrifluoroethylenes, poly(vinyl fluorides), poly(vinylidene fluoride)s, tetrafluoroethylene-hexafluoropropylene copolymers, and chlorofluoroethylene-vinylidene fluoride copolymers. Examples of the nonpolar polymers constituting the nonpolar-polymer low-adhesive bases include olefinic resins such as polyethylenes and polypropylenes. The release liner(s) can be formed according to a known or customary process. The thickness and other parameters of the release liner(s) are not specifically limited.

The double-sided pressure-sensitive adhesive tape according to the present invention can be adopted to any application not limited and is adopted typically to the fixation of electronic parts. Among such applications, from the viewpoint of workability, the double-sided pressure-sensitive adhesive tape is especially preferably adopted to the fixation of a wiring circuit board (especially preferably an FPC).

[Wiring Circuit Board]

A wiring circuit board according to an embodiment of the present invention includes at least an electrically insulating layer (hereinafter also referred to as a “base insulating layer”); and an electrically conducting layer (hereinafter also referred to as a “conducting layer”) present on the base insulating layer so as to form a predetermined circuit pattern and further includes the double-sided pressure-sensitive adhesive tape according to the present invention affixed to the back side thereof (i.e., a side of the base insulating layer opposite to the conducting layer). The wiring circuit board according to the present invention can therefore be fixed to a support such as a reinforcing plate by using the double-sided pressure-sensitive adhesive tape affixed to the back side.

Where necessary, the wiring circuit board according to the present invention may further include one or more other layers such as an electrically insulating layer arranged on the conducting layer to cover the conducting layer (hereinafter also referred to as a “cover insulating layer”), in addition to the base insulating layer and the conducting layer present on the base insulating layer so as to form a predetermined circuit pattern.

The wiring circuit board may have a multilayer structure including two or more wiring circuit boards being laminated with each other. In such wiring circuit board having a multilayer structure, the number of wiring circuit board (the number of layers) is not critical, as long as being 2 or more.

The wiring circuit board according to the present invention is not especially limited, as long as being a wiring circuit board, but is preferably a flexible printed circuit board (FPC). The wiring circuit board according to the present invention is advantageously usable as a wiring circuit board for use in various electronic instruments.

(Base Insulating Layer)

The base insulating layer is an electrically insulating layer formed from an electrically insulating material. The electrically insulating material for forming the base insulating layer is not especially limited and can be chosen as appropriate from among electrically insulating materials for use in known wiring circuit boards. Specifically, exemplary electrically insulating materials include plastic materials such as polyimide resins, acrylic resins, poly(ether nitrile) resins, poly(ether sulfone) resins, polyester resins (e.g., poly(ethylene terephthalate) resins and poly(ethylene naphthalate) resins), poly(vinyl chloride) resins, poly(phenylene sulfide) resins, poly(ether ether ketone) resins, polyamide resins (e.g., so-called “aramid resins”), polyarylate resins, polycarbonate resins and liquid crystal polymers; ceramic materials such as alumina, zirconia, soda-lime glass and quartz glass; and various electrically insulating (non-electroconductive) composite materials. Each of different electrically insulating materials can be used alone or in combination.

Plastic materials are preferred as the electrically insulating material for use herein, of which polyimide resins are more preferred. Accordingly, the base insulating layer is preferably formed from a plastic film or sheet and more preferably formed from a polyimide resin film or sheet. As the electrically insulating material, a photosensitive electrically insulating material (including a photosensitive plastic material such as a photosensitive polyimide resin) can also be used.

The base insulating layer may have a single-layer structure or multilayer structure. The surface of the base insulating layer may have been subjected to a surface treatment such as corona discharge treatment, plasma treatment, surface roughening, and/or hydrolyzing. Though not critical, the base insulating layer has a thickness choosable within ranges of typically from 3 to 100 μm, preferably from 5 to 50 μm and more preferably from 10 to 30 μm.

(Conducting Layer)

The conducting layer is an electrically conducting layer formed from an electroconductive material. The conducting layer is arranged on or above the base insulating layer so as to form a predetermined circuit pattern. The electroconductive material for forming the conducting layer is not especially limited and can be chosen as appropriate from among electroconductive materials for use in known wiring circuit boards. Specific examples of such electroconductive materials include metallic materials including copper, nickel, gold, and chromium, as well as various alloys (e.g., solder) and platinum; and electroconductive plastic materials. Each of different electroconductive materials can be used alone or in combination. Metallic materials are preferred as the electroconductive material for use in the present invention, of which copper is more preferred.

The conducting layer may have a single-layer structure or multilayer structure. The surface of the conducting layer may have been subjected to one or more surface treatments. Though not critical, the conducting layer has a thickness choosable within ranges of typically from 1 to 50 μm, preferably from 2 to 30 μm and more preferably from 3 to 20 μm.

The way to form the conducting layer is not especially limited and is choosable from among known formation techniques for conducting layers, including known patterning processes such as subtractive process, additive process, and semi-additive process. Typically, when to be arranged directly on the surface of the base insulating layer, the conducting layer can be provided by forming a layer of an electroconductive material as a predetermined circuit pattern on the base insulating layer typically through plating or vapor deposition. Exemplary techniques usable herein include electroless plating, electrolytic plating, vacuum vapor deposition, and sputtering.

(Cover Insulating Layer)

The cover insulating layer is a covering electrically insulating layer (protective electrically insulating layer) which is formed from an electrically insulating material and covers the conducting layer. The cover insulating layer may be provided according to necessity and is not necessarily provided. The electrically insulating material for constituting the cover insulating layer is not especially limited and can be chosen from among electrically insulating materials for use in known wiring circuit boards, as in the base insulating layer. Specific examples of electrically insulating materials for constituting the cover insulating layer include the electrically insulating materials listed above as the electrically insulating materials for the formation of the base insulating layer. Among them, plastic materials are preferred, of which polyimide resins are more preferred, as in the base insulating layer. Each of different electrically insulating materials can be used alone or in combination for the formation of the cover insulating layer.

The cover insulating layer may have a single-layer structure or multilayer structure. The surface of the cover insulating layer may have been subjected to one or more surface treatments such as corona discharge treatment, plasma treatment, surface roughening, and (hydrolyzing. Though not critical, the cover insulating layer has a thickness choosable within a range of preferably from 3 to 100 μm, more preferably from 5 to 50 μm, and furthermore preferably from 10 to 30 μm.

The way to form the cover insulating layer is not especially limited and can be suitably chosen from among known formation techniques. Exemplary formation techniques include a technique of applying a layer of a liquid or melt containing an electrically insulating material, and drying the applied layer; and a technique of previously forming a film or sheet corresponding to the dimensions of the conducting layer and including an electrically insulating material, and laying the film or sheet on the conducting layer.

[Reinforcing Plate]

The wiring circuit board according to the present invention may, for example, be used by being fixed to a support such as a reinforcing plate. Such a reinforcing plate is usually arranged on a side (back side) of the base insulting layer opposite to the conducting layer. The reinforcing material used for the formation of the reinforcing plate is not especially limited but it may be appropriately chosen from among known reinforcing plate materials for the formation of reinforcing plates. The reinforcing plate material may be one having electric conductivity or one having no electric conductivity. More specifically, exemplary reinforcing plate materials include metal materials such as stainless steel, aluminum, copper, iron, gold, silver, nickel, titanium and chromium; plastic materials such as polyimide resins, acrylic resins, poly(ether nitrile) resins, poly(ether sulfone) resins, polyester resins (such as poly(ethylene terephthalate) resins and poly(ethylene naphthalate) resins), poly(vinyl chloride) resins, poly(phenylene sulfide) resins, poly(ether ether ketone) resins, polyamide resins (such as so-called “aramid resins”), polyarylate resins, polycarbonate resins, epoxy resins, glass epoxy resins and liquid crystal polymers; and inorganic materials such as alumina, zirconia, soda glass, quartz glass and carbon. Each of different reinforcing materials may be used alone or in combination.

As the reinforcing plate material, metallic materials such as stainless steel and aluminum, and plastic materials such as polyimide resins are advantageous and, among them, stainless steel and aluminum are especially advantageously usable. Accordingly, the reinforcing plate is preferably formed of a metal foil or metal plate (such as stainless steel foil or plate, or aluminum foil or plate) or a plastic film or sheet (such as a film or sheet made of polyimide resin.

The reinforcing plate may have a single-layer structure or multilayer structure. The surface of the reinforcing plate may have been subjected to one or more surface treatments. Though not critical, the reinforcing plate has a thickness choosable within a range of typically from 50 to 2000 μm and preferably from 100 to 1000 μm.

### EXAMPLES

The present invention will be illustrated in further detail with reference to several working examples below. It should be noted, however, that these examples are never construed to limit the scope of the present invention. The compositions and structures of double-sided pressure-sensitive adhesive tapes prepared in the examples and a comparative example are shown in Table 2.

### Example 1

A nonwoven fabric substrate used herein was a nonwoven fabric prepared from 80 percent by weight of Manila hemp and 20 percent by weight of wood pulp through paper making according to a technique using a cylinder paper machine, as shown in Table 2.

After nitrogen purging, solution polymerization of 90 parts by weight of 2-ethylhexyl acrylate and 10 parts by weight of acrylic acid was performed in 210 parts by weight of ethyl acetate in the coexistence of 0.4 part by weight of 2,2′-azobisisobutyronitrile while stirring at a temperature of from 60° C. to 80° C., to give an acrylic polymer solution having a viscosity of about 120 poises, a degree of polymerization of 99.2% and a solids content of 30.0 percent by weight.

The solution was combined with, per 100 parts by weight of the acrylic polymer, 20 parts by weight of a terpene-phenolic tackifier resin (trade name “YS Polyster S145” supplied by Yasuhara Chemical Co., Ltd., having a softening point of 145° C.) and 0.05 part by weight of a multifunctional epoxy crosslinking agent (trade name “TETRAD C” supplied by Mitsubishi Gas Chemical Company, Inc.) to give a pressure-sensitive adhesive composition.

The pressure-sensitive adhesive composition was applied to a surface of a release liner using a coater and dried at 130° C. for 5 minutes to form a pressure-sensitive adhesive layer 24 μm thick. The release liner included glassine paper and a release coating layer formed from a silicone release coating agent on a surface of the glassine paper, and the composition was applied to the surface of the release coating layer. Next, two pressure-sensitive adhesive layers thus prepared were laminated and transferred to the both sides of the nonwoven fabric substrate and thereby yielded a double-sided pressure-sensitive adhesive tape having a structure of (pressure-sensitive adhesive layer)/(nonwoven fabric substrate)/(pressure-sensitive adhesive layer).

### Examples 2 and 3, Comparative Example 1

A series of double-sided pressure-sensitive adhesive tapes was prepared by the procedure of Example 1, except for changing, for example, the thickness of the nonwoven fabric substrate and/or of the pressure-sensitive adhesive layers.

(Evaluation)

The double-sided pressure-sensitive adhesive tapes obtained in the examples and the comparative example were evaluated on the following properties. The evaluation results are shown in Table 2.

### (1) Handleability (Resistance to Substrate Breakage) of Double-Sided Pressure-Sensitive Adhesive Tape During Production

In the productions of the double-sided pressure-sensitive adhesive tapes in the examples and the comparative example, whether the substrate (nonwoven fabric substrate) readily broke or not was evaluated according to the following criteria:

Good: The substrate is resistant to breakage when it is handled during production;

Poor: The substrate is susceptible to breakage and is hard to handle during production.

### (2) Appearance of Adhesive Surface (Pressure-Sensitive Adhesive Layer Surface) After Reflow Process

After removing a release liner on one side of the tape to expose an adhesive face, the exposed adhesive surface of each of the double-sided pressure-sensitive adhesive tapes prepared in the examples and the comparative example was affixed, using a hand roller, to a model FPC having properties indicated in Table 1 below. Next, the adhesive surface was pressed and bonded to the model FPC using a laminator under conditions of a temperature of about 60° C. and a pressure of 0.4 MPa to give a series of laminate samples. The laminate samples were passed through a reflow process under such heating conditions that the peak temperature was 260° C.

The other release liner was then removed, the appearance of the adhesive surface was observed and evaluated according to the following criteria:

Good: The adhesive surface shows very small unevenness and has good appearance;

Fair: The adhesive surface shows small unevenness but it is practically acceptable;

Poor: The adhesive surface shows large unevenness and has poor appearance.

TABLE 1
(Properties of Model FPC)

| | Cu | Pl | Cu | Thickness |
|---|---|---|---|---|
| Double-sided FPC | 1 oz | 1 mil | 1 oz | about 180 μm |

TABLE 2

| | | | | Example 1 | Example 2 | Example 3 | Com. Ex. 1 |
|---|---|---|---|---|---|---|---|
| Nonwoven fabric | Nonwoven fabric | | (weight percent) | Manila hemp (80) | Manila hemp (80) | Manila hemp (80) | Manila hemp (80) |
| substrate | | | (weight percent) | Wood pulp (20) | Wood pulp (20) | Wood pulp (20) | Wood pulp (20) |
| | Paper-making process | | | cylinder | cylinder | cylinder | cylinder |
| | Basis weight | | (g/m²) | 5.7 | 7.4 | 7.6 | 5.5 |
| | Thickness | | (μm) | 16 | 17 | 18 | 14 |
| | Tensile strength | MD | (N/15 mm) | 4.4 | 7.4 | 9.3 | 3.4 |
| | | TD | (N/15 mm) | 0.3 | 0.5 | 0.8 | 0.2 |

| Thicknesses of pressure- | (μm) | 24/24 | 23/23 | 23/23 | 24/24 |
|---|---|---|---|---|---|
| sensitive adhesive layers | | | | | |
| Lamination process of | | transfer/transfer | transfer/transfer | transfer/transfer | transfer/transfer |
| pressure-sensitive adhesive layer | | | | | |
| Total thickness of double-sided | (μm) | 50 | 50 | 50 | 50 |
| pressure-sensitive adhesive tape | | | | | |

| | | | | | |
|---|---|---|---|---|---|
| Evaluation results | Handleability (resistance to substrate breakage) | Good | Good | Good | Poor |
| | of double-sided pressure-sensitive adhesive | | | | |
| | tape during production | | | | |
| | Appearance of adhesive surface (pressure- | Good | Fair | Fair | Good |
| | sensitive adhesive layer surface) | | | | |
| | after reflow process | | | | |

Table 2 demonstrates that the double-sided pressure-sensitive adhesive tapes according to the present invention (Examples) are thin but do not break during production and processing, show good appearance even after a reflow process, and have excellent productivity and workability.

### INDUSTRIAL APPLICABILITY

The double-sided pressure-sensitive adhesive tapes according to the present invention are thin and are thereby effective for the reduction in size and thickness of products using the tapes for fixing. They have high strengths in the machine direction and are thereby resistant to tape breakage during production and processing processes. In addition, they each have a nonwoven fabric substrate and thereby excel in punching quality. They are therefore industrially useful and are particularly useful as double-sided pressure-sensitive adhesive tapes for fixing electronic parts, such as those for fixing wiring circuit boards (particularly for fixing FPCs).

1. A double-sided pressure-sensitive adhesive tape comprising a nonwoven fabric substrate; and a pair of pressure-sensitive adhesive layers present on both sides of the substrate, the nonwoven fabric substrate containing at least Manila hemp, having a thickness of 18 μm or less and having a tensile strength in a machine direction of 4 N/15 mm or more.

2. The double-sided pressure-sensitive adhesive tape according to claim 1, wherein the pressure-sensitive adhesive layers are formed from a pressure-sensitive adhesive composition containing an acrylic polymer as a principal component and further containing a tackifier resin having a phenolic hydroxyl group.

3. The double-sided pressure-sensitive adhesive tape according to claim 1, adopted to a wiring circuit board.

4. A wiring circuit board comprising an electrically insulating layer; and an electrically conducting layer present on or above the electrically insulating layer so as to form a predetermined circuit pattern, wherein the wiring circuit board further comprises the double-sided pressure-sensitive adhesive tape according to claim 3 affixed to a back side of the wiring circuit board.

5. The double-sided pressure-sensitive adhesive tape according to claim 2, adopted to a wiring circuit board.

6. A wiring circuit board comprising an electrically insulating layer; and an electrically conducting layer present on or above the electrically insulating layer so as to form a predetermined circuit pattern, wherein the wiring circuit board further comprises the double-sided pressure-sensitive adhesive tape according to claim 5 affixed to a back side of the wiring circuit board.
